(19) United States
(12) Patent Application Publication
(10) Pub. No.: US 2021/0313120 A1
(43) Pub. Date: Oct. 7, 2021

(54) MXene-Modified Hybrid Photoconverter

(71) Applicant: Natonal University of Science and Technology MISIS, Moscow (RU)

(72) Inventors: Anna Ivanovna PAZNIAK, Moscow (RU); Danila Sergeevich SARANIN, Aprelevka (RU); Dmitry Sergeevich MURATOV, Lytkarino (RU); Pavel Andreevich GOSTISHCHEV, Pos. Zelenyj (RU); Sergei Ivanovich DEDENKO, Moscow (RU); Denis Valerievich KUZNETSOV, Moscow (RU); Al'do Dl CARLO, Rom (IT)

(73) Assignee: Natonal University of Science and Technology MISIS, Moscow (RU)

(21) Appl. No.: 17/056,869

(22) PCT Filed: Sep. 20, 2019
(86) PCT No.: PCT/RU19/00661

§ 371 Date: Nov. 19, 2020

(30) Foreign Application Priority Data
Dec. 25, 2018 (RU) 2018146146

(51) Int. Cl. H01G 9/20; H01G 9/00; H01L 51/00; H01L 51/42; H01L 51/44

(52) U.S. Cl. CPC H01G 9/2009; H01G 9/0036; H01L 51/0096; H01L 51/4253; H01L 51/4293; H01L 51/0048; H01L 51/0003; H01L 51/0026; H01L 51/0023; H01L 51/0077; H01L 51/442

(57) ABSTRACT

The disclosed photoconverter is related to the technology of thin-film hybrid semiconductor photoconverters. Thin-film hybrid photoconverters with heterojunctions and layers is modified with Ti₃C₂Tₓ MXenes for use in visible sunlight spectrum and UV-IR regions (380 to 780 nm). The device with absorber layer of metal-organic APbX₃ perovskites was fabricated in n-i-p and p-i-n configurations, including structures with carbon electrodes, and stabilized characteristics were stabilized by introduction of thin Ti₃C₂Tₓ MXene layers (5-50 nm) at the junction and contact interfaces, i.e., APbX₃ perovskite absorber layer/MXene, electron transport layer/MXene, cathode electrode/MXene, as well as by doping of carbon electrode for reduction of the work function by incorporating of MXenes into the bulk of material with appropriate weight percentage for providing ohmic contact with higher efficiency of charge collection.

### CROSS-REFERENCE TO RELATED APPLICATIONS

This application is a U.S. national stage application of an international application PCT/RU2019/000661 filed on 20 Sep. 2019, whose disclosure is incorporated herein in its entirety by reference, which international application claims priority of a Russian Federation patent application RU2018146146 filed on 25 Dec. 2018.

### FIELD OF THE INVENTION

This invention belongs to the technology of thin-film hybrid semiconductor photoconverters and can be used for the fabrication of solar cells and modules for terrestrial application, photodetectors for visible range of solar light (380 to 780 nm) and as well as for near ultraviolet (from 300 nm) wavelength region.

### BACKGROUND OF THE INVENTION

There are several approaches for use of Mxenes in optoelectronics. Technology for MXene-silicon heterostructure photoconverter (solar cell) s presented in the literature. (Zhe Kang et al., MXene-Silicon Van Der Waals Heterostructures for High Speed Self Driven Photoconverter (solar cell) s, Advanced Electronic Materials, volume 3, issue 9, https://doi.org/10.1002/aelm.201700165, 2017). The device is based in vertical Van Der Waals heterostructures with Ti₃C₂T_{X} films (with a work function of 4.37 eV) on n-Si. The Ti₃C₂T_{X} layer in the devices works not only as the transparent electrode, but also contributes to the separation and transport of photo-induced carriers. After investigations of the dependence between annealing temperature, illumination, and applied voltage on the performance of Ti₃C₂T_{X}/n-Si Schottky junction heterostructures, a photoconverter (solar cell) was fabricated with high response speeds in the order of milliseconds and sensitivity of 26 mA W⁻¹ under illumination of 405 nm laser.

A disadvantage of this technology and device is the narrow spectral region which does not cover the entire visible range. The report about use of MXenes for electrode materials in CMOS devices (KR20160164133A, published 5 Dec. 2016). The invention describes the method of MXene synthesis for application in electrode materials. The method includes procedure of fabrication of the MAX phase (Ti₂AlC), treatment of the obtained bulk MAX material by a hydrofluoric acid (HF) solution and extracting of the treated bulk MAX material in the form of a 2D thin-film material with use of physical exfoliation methods. The obtained material was used as the electrode (inverter electrode) of CMOS with differential structure included n-MoS₂ channel, p-WSe₂ channel, and second MXene film based source electrode and a drain electrode. Thus, the time of CMOS device fabrication can be significantly reduced. A disadvantage of the patent is a narrow application range of the new electrode, without taking into account the use the unique properties—low work function.

It was reported about the technology of MXene incorporation into the absorber layer of perovskite solar cells (Zhanglin Guo et al., High Electrical Conductivity 2D MXene Serves as Additive of Perovskite for Efficient Solar Cells, Small, https://doi.org/10.1002/smll.201802738; 2018 pp: 1802738). The Ti₃C₂Tx MXene were incorporated into the bulk of perovskite absorber layer for enhancement of the power conversation efficiency. Results showed that the termination groups of Ti₃C₂Tx can retard the crystallization rate, thereby increasing the crystal size of ABX₃ molecule such as CH₃NH₃PbI₃. It was found that the high electrical conductivity and mobility of MXene can improve the charge transfer. After optimizing the key parameters, 12% enhancement in device performance was achieved with addition of 0.03 wt % amount of MXene.

A disadvantage of technology described in the papers absence of stability at electrode contacts and heterojunction boundaries which is the major problem of perovskite solar cell, moreover enhancement of in device performance was reported at 1-2% of the PCE for 0.03 wt % amount of MXene additive.

The closest counterpart of the invention disclosed herein is a perovskite solar cell technology using MXenes (metal carbides and nitrides) (CN 201810267605, published 31 Aug. 2018). Said invention relates to the technology of photoelectric solar cells with the incorporation of 2D carbides or nitrides of transition metals into perovskite solar cells and methods of their fabrication. The main structure of the perovskite solar cell comprises a transparent electrode, an electron transport layer, a perovskite abrosber layer, a hole transport layer and an anti-electrode. The low-dimension transition metal carbide or nitride (MXene) in the device structure can function as the electrode, the hole transport layer or any of the electrode layers; alternatively or simultaneously the transparent electrode; the doping material or the heteroarile absorber layer in the perovskite; or part of the transparent electrode, resulting in an increase in the conductivity of the electrode. The use of 2D transition metal carbide or nitride can increase the conductivity of the transparent electrode and increase the stability and performance of perovskite solar cells.

A disadvantage of said invention is the lack of stability of electrode contacts and heterojunction boundaries which is the major problem of perovskite solar cell engineering.

### SUMMARY OF THE INVENTION

The technical result of the invention disclosed herein is increasing the performance and stability of hybrid photoconverters (solar cells) based of APbX₃ hybrid perovskites via incorporation of thin MXene interlayers (5-50 nm) at the absorber layer/transport layer (hole or electron) heterostructure junction and at the electrode contact interface. For p-i-n and n-i-p structures, MXene incorporation at the hole transport layer/perovskite absorber layer interface allows achieving a relative performance enhancement by more than 15% due to an increase in the open-circuit voltage of the devices by more than 10% to >1.10 V and an increase in the filling factor of the device (in output IV curve) by more than 5% (>0.75) due to a decrease in the shunting leakage current and contact resistance.

The technical result of the invention disclosed herein is achieved as follows. A thin-film hybrid photoconverter (solar cell) is fabricated on the transparent substrate with sequentially deposited transparent electrode and a photoactive layer, which is located between the p- and n-type transport layers, on the top one of which a nontransparent electrode is placed, wherein photoactive layer is made from APbX₃ hybrid perovskites, where

A are organic or inorganic cations e.g. CH3NH3+; CH5N2+; Cs+; CH6N3+; (NH3)BuCO2H+);

X3 are halide elements of the I; Br; Cl group,

and at all the heterojunction boundaries and metal/semiconductor boundaries there are 5-50 nm thick Ti₃C₂Tx MXene layers,

where Tx are functional groups terminating the surface of the 2D materials, Tx=O—, OH—, F—.

Substrate is made from glass or quartz or plastic.

Substrate thickness is 50-750 micrometers.

Nontransparent electrode is made of Ag or Cu or Al or a ceramic material or carbon nanotubes.

In a specific embodiment MXenes can have the next formulation Ti₃C₂Tₓ, where Tₓ is predominantly (55-60%) F— with a work function of 4.2-3.8 eV.

Alternatively, MXenes can have the next formulation Ti₃C₂Tₓ, where Tₓ is predominantly (65-70%) O— and OH— with a work function of 5.5-4.9 eV.

Also, MXenes can have the next formulation Ti₃C₂Tₓ, where Tₓ is predominantly (70-75%) O— and F— with a work function of 4.7-3.8 eV.

In some specific embodiments MXenes can have the next formulation Ti₃C₂Tₓ, where Tₓ is predominantly (55-60%) O— with a work function of 5.5-4.7 eV.

Furthermore, MXenes can have the next formulation Ti₃C₂Tₓ, where Tₓ is predominantly (45-50%) OH— with a work function of 4.0-1.8 eV.

### BRIEF DESCRIPTION OF THE DRAWINGS

The invention will be now illustrated with drawings, wherein

FIG. 1 shows standard non-modified architectures of a photoconverter (solar cell) having a p-i-n configuration (FIG. 1 (a)) with a transparent anode and a photoconverter (solar cell) having an n-i-p configuration (FIG. 1 (b)) with a transparent cathode.

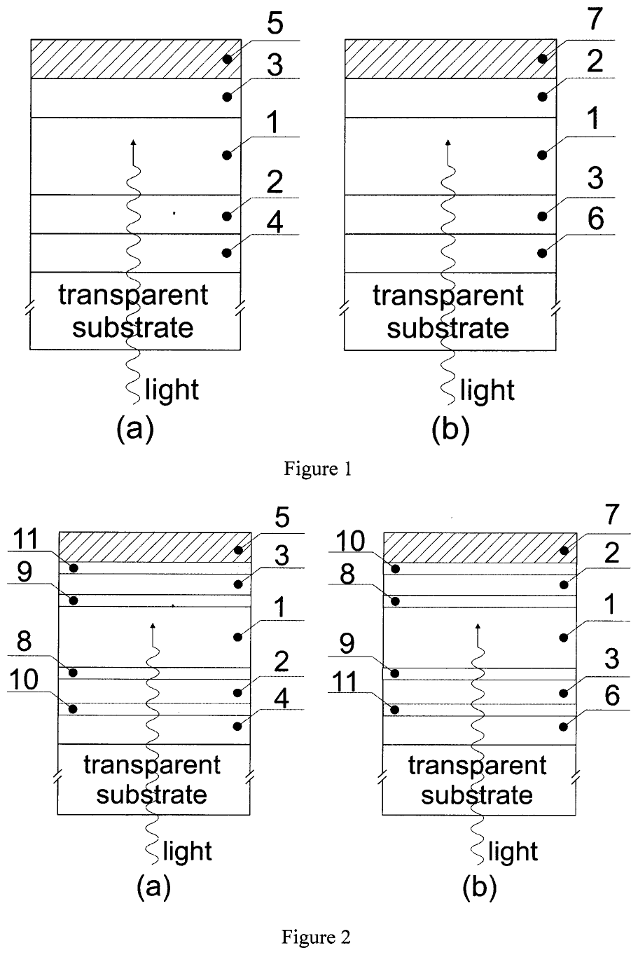

The explanation is accompanied with layer markings in the device structure as follows: 1 is the photoactive perovskite layer, 2 is the hole transport layer, 3 is the electron transport layer, 4 is the transparent anode, 5 is the non-transparent cathode, 6 is the transparent cathode and 7 is the non-transparent anode. FIG. 2 shows similar photoconverter (solar cell) architectures modified with MXenes, where the types of materials for the respective junctions are shown: 8 are MXenes for the modification of the APbX₃ perovskite absorber layer/hole transport layer heterojunction, 9 are MXenes for the modification of the APbX₃ perovskite absorber layer/electron transport layer heterojunction, 10 are MXenes for the modification of the hole transport layer/anode contact and 11 are MXenes for the modification of the electron transport layer/cathode contact.

Increasing the stability of the device is achieved by the passivation of the heterojunction boundaries and a reduction of the concentration of traps at the interfaces due to the incorporation of MXene layers with different work functions, as well as by a reduction of the diffusion of materials from the device structure layers to the bulk and their electrochemical interaction through the use of modified MXenes functioning as diffusion barrier (buffer) layers. The specific results of photoconverter (solar cell) stabilization are illustrated for a number of device architectures.

For inverted p-i-n planar solar cells:

Stabilization of the non-transparent electrode/electron transport layer junction, increase in the relative stability of the position of the maximum power point under constant illumination (spectrum 1.5 AM G; 100 mW/cm²) by 34% in 48 h due to the incorporation of a MXene layer (5-50 nm) between the transport layer and the electrode;

For n-i-p solar cells:

Reduction of the relative hysteresis level of the VACs by 60% (to a less than 0.25 hysteresis index) due to the incorporation of a 5-50 nm MXene layer into the heterojunction boundary between the electron transport layer and the hole transport layer. Stabilization of the non-transparent electrode/hole transport layer junction, increases in the relative stability of the position of the maximum power point under constant illumination (spectrum 1.5 AM G; 100 mW/cm²) by 40% in 48 h due to the incorporation of a MXene layer (5-50 nm) between the transport layer and the electrode.

Thin-film hybrid photoconverter (solar cell) s with heterojunctions and Ti₃C₂Tₓ MXene-modified layers operate in the 380-780 nm visible sunlight region and the near UV-A region (300+ nm) and have the p-i-n and n-i-p configurations on the basis of APbX₃ hybrid perovskites.

For the p-i-n and n-i-p photoconverter (solar cell) structures, the incorporation of MXenes at the hole transport layer/perovskite absorber layer interface leads to a relative increase in the device performance by more than 15% due to an increase in the open-circuit voltage of the devices by more than 10% to >1.10 V and an increase in the filling factor of the device VAC by more than 5% (>0.75) due to a decrease in the shunting leakage current and an increase in the contact voltage; for a n-i-p perovskite solar cell with a carbon electrode in the architecture, the relative increase in the device performance is more than 20% due to a decrease in the contact resistance with a decrease in the carbon cathode work function by 0.5 eV (to −4.5 eV); the device performances (Pmax under standard illumination of ground-based photoconverter (solar cell) s, spectrum 1.5 AM G, P_{carrier} 100 mW/cm²) were stabilized by the incorporation of thin Ti₃C₂Tₓ MXene layers (5-50 nm) at the junction boundaries and contacts for surface passivation and by providing the following diffusion barriers: between the APbX₃ perovskite absorber layer and the electron transport layer (MXene work function −4.2 to −3.8 eV); between the cathode electrode and the electron transport layer (MXene work function −4.7 to −3.8 eV); between the APbX₃ perovskite absorber layer and the hole transport layer (MXene work function −5.5 to −4.9 eV); between the hole transport layer and the anode (MXene work function −3.8 to −4.7 eV).

### PREFERRED EMBODIMENTS OF THE INVENTION

The subject matter of the invention is increase of the performance and stability of the perovskite solar cells due to the incorporation of ultrathin Ti₃C₂Tₓ MXene layers (5-30 nm) at the following heterojunction boundaries:
the APbX₃ perovskite absorber layer/the electron (hole) transport layer;
the electron (hole) transport layer/the cathode (anode) layer.

As a result of selective chemical etching of the MAX phase precursor aiming at etching out the aluminum layer, the surface of the single MXene flakes becomes terminated by the fluorine and oxygen containing functional groups. In accordance with the first principle calculations, the electron work function for —OH, —O and —F terminated MXenes is determined by the dipole moments generated due to the charge transfer between the functional groups and the MXenes and a change in the overall number of dipole moments as a result of surface relaxation.

—OH group-terminated MXenes have ultralow electron work functions of 1.6 to 2.8 eV whereas —O group-terminated ones have high electron work functions of 5.75 to 6.25 eV.

The average sizes and thicknesses of the unit MXene flakes are in the 0.5-5 nm and 1.0-1.5 nm ranges, respectively, and are determined by the type of the chemicals used for selective etching and, most importantly, by the delamination method. However, regardless of the synthesis method, precision control of sizes of individual particles is a complex task. Experiments showed that the use of ultrasonication provides for less defect-containing single flakes with an average size of 1.5-2.5 micrometer. The MXene electron work function for the Ti₃C₂Tₓ composition can be varied in a wide range by controlling the chemistry of the surface. Low electron work functions (3.5-4.0 eV) are observed in MXenes with predominant fluorine ions on the particle surface (˜20-25 at. %). For “softer” synthesis modes the amount of —F decreases and the amount of —O increases, this being accompanied by a gradual increase in the electron work function from 4.2 to 4.6 eV. MXenes with electron works functions of within 5.0 eV or higher can be obtained by reducing the concentration of —F on the particle surface through changing the ratio of reactants, e.g. Ti₃AlC₂:LiF:HCl. As a result of selective chemical etching of the MAX phase precursor aiming at etching out the aluminum layer, the surface of the unit MXene flakes becomes terminated by the fluorine and oxygen containing functional groups. In accordance with the first principle calculations, the electron work function for —OH, —O and —F terminated MXenes is determined by the dipole moments generated due to the charge transfer between the functional groups and the MXenes and a change in the overall number of dipole moments as a result of surface relaxation. —OH group-terminated MXenes have ultralow electron work functions of 1.6 to 2.8 eV whereas —O group-terminated ones have high electron work functions of 5.75 to 6.25 eV.

Based on the above statements, the following four MXene configurations were chosen for MXene layer incorporation into the structure in the invention disclosed herein:

Configuration 1: MXenes for modification of the heterojunction between the APbX₃ perovskite absorber layer and the electron transport layer. The MXene work functions range from −3.8 to −4.2 eV;

Configuration 2: MXenes for modification the heterojunction between the APbX₃ perovskite absorber layer and the hole transport layer. The MXene work functions range from −4.9 to −5.5 eV;

Configuration 3: MXenes for modification of the contact between the electron transport layer and the electrode. The MXene work functions range is from −3.8 to −4.7 eV;

Configuration 4: MXenes for modification of the contact between the hole transport layer and the electrode. The MXene work functions range is from −4.7 to −5.5 eV.

The stability of the photoconverter (solar cell) s increases due to the reduction of the diffusion of metals from non-transparent electrodes, cation ions (A—site cations of perovskite molecule), APbX₃ perovskite decomposition products (e.g. —I ions, HI acid, lead salts etc.) if thin (5-50 nm) Ti₃C₂ Tₓ diffusion barrier (buffer) layers are used and due to their chemical and electrochemical stability against charge transfer during photoconverter (solar cell) operation.

Furthermore, the synthesis of 5-50 nm thick Ti₃C₂ Tₓ MXene transition layers allows achieving surface passivation at the heterojunction boundary between the perovskite photoactive layer and the transport layer, this considerably reducing the concentration of accumulated vacancy defects (perovskite cations and anions), parasitic capacitances and, as a result, hysteresis in VACs (to a hysteresis index of below 0.25) which negatively affects the maximum power of perovskite solar cells.

The incorporation of a 5-50 nm thick Ti₃C₂ Tₓ transition layer at the interface of the junction between the electron transport layer (polymer or fullerene acceptors, metal oxides SnO₂; ZnO; TiO₂; ZrO₂) and the electrode (metals Ag, Cu, Al, ceramic materials e.g. ITO (tin doped indium oxide In₂O₃:Sn); FTO (fluorine doped tin oxide SnO₂:F); AZO (aluminum doped zinc oxide ZnO:Al); IZO (zinc doped indium oxide In₂O₃Zn); BZO (boron doped zinc oxide ZnO:B)) allows one to efficiently equalize the energy levels of the conduction band (or the lowest vacant molecular orbit) of the transport layer and the work function of the metal thus providing an ohmic contact, absence of potential barriers (a Shottky contact) and level mismatch energy losses (˜0.2-0.3 eV) due to the uniquely low Ti₃C₂ work function (Wf<2.0 eV).

A dramatic change in the work function of the carbon electrode (Wf=0.5 eV) by more than 0.1-(≥0.3) eV due to the incorporation of Ti₃C₂ with a variable weight ratio allows using a composite material as the anode or the cathode for hole and electron collection in n-i-p and p-i-n structures, respectively.

Photoactive layer 1 having the molecular formula ABX₃ can be synthesized from a variety of modifications of hybrid perovskites where the cation A can be organic (methyl ammonium CH₃NH₃, formamidine CH₅N₂, guanidine CH₆N₃.) or inorganic compounds (Cs etc.), the anion B can be an element selected from Pb, Sn, AgBi (double B-side cation), and the anion X can be a halide selected from I, Br, Cl, with a thickness of 100 to 800 nm depending on the photoconverter (solar cell) intended use. Photoactive layer 1 can be deposited using liquid methods (spin coating, spraying, scalpel or slot matrix printing) or vacuum methods (thermal resistive evaporation).

Hole transport layers 2 in the photoconverter (solar cell) structure can be synthesized from materials selected from metal oxides (NiO, CuO, Cu₂O, MoOₓ, Nb₂O₅, WO₃, CoO, grapheme oxide), metal sulfides (MoS₂, WS₂), organic semiconductors (PEDOT:PSS; P3HT; PCDTBT; PTAA; Spiro-Ometad; CuPc, PANI (etc.) and inorganic metal salts (CuSCN; CuI etc.), with a thickness of 5 to 100 nm depending on the photoconverter (solar cell) intended use. Hole transport layer 2 can be deposited using liquid methods (spin coating, spraying, scalpel, slot matrix or jet printing) or vacuum methods (thermal resistive evaporation, magnetron sputtering).

Electron transport layers 3 in the photoconverter (solar cell) structure can be synthesized from materials selected from metal oxides (SnO₂; ZnO; TiO₂; ZrO₂), metal sulfides (MoS₂, CdS) and organic semiconductors (C60/C70 and their derivatives, ITIC and its derivatives, perylene base compounds), with a thickness of 5 to 200 nm depending on the photoconverter (solar cell) intended use. Electron transport layer 3 can be deposited using liquid methods (spin coating, spraying, scalpel, slot matrix or jet printing) or vacuum methods (thermal resistive evaporation, magnetron sputtering).

Transparent electrodes 4 and 6 (cathode or anode depends on the architecture orientation) can be synthesized from materials selected from ITO (tin doped indium oxide In₂O₃:Sn), FTO (fluorine doped indium oxide SnO₂:F), AZO (aluminum doped zinc oxide ZnO:Al), IZO (zinc doped indium oxide In₂O₃Zn), BZO (boron doped zinc oxide ZnO:B), carbon nanotubes, metal microwires, heavily doped PEDOT:PSS, with a thickness of 100 to 750 nm depending from the architecture of used photoconverter (solar cell). Transparent electrodes 4 and 6 can be deposited using liquid methods (spin coating, spraying, scalpel, slot matrix or jet printing) or vacuum methods (thermal resistive evaporation, magnetron sputtering, epitaxy).

Non-transparent electrodes 5 and 7 (cathode or anode depending on the architecture orientation) can be deposited with use of materials as Ag, Au, Cu, Al, C, carbon nanotubes and deposited using vacuum methods (thermal e evaporation, magnetron sputtering for the metals Ag, Au, Cu, Al) with a thickness of up to 200 nm for metals and liquid methods of carbon electrode printing (doctor blade, slot die printing) with a thickness of up to 2.5 um.

The device structures are fabricated on glass or quartz substrates with thicknesses of 40 um to 3.2 mm with a SiO₂ barrier layer or on PET, PEN or mylar plastic substrates with thicknesses of 50 to 750 um.

Ti₃C₂Tₓ was obtained by selective chemical etching of aluminum from the fine-dispersed MAX phase precursor Ti₃AlC₂. The etchants were lithium fluoride (LiF) and a 6M hydrochloric acid solution with a Ti₃AlC₂:LiF:HCl molar ratio of 1:7.5:25. Chemical etching was carried out with permanent solution stirring in a magnetic stirrer at a 200 rpm rate at 35° C. for 24 h. Etching was followed by multiple cleaning from reaction products until reaching close-to-neutral pH, filtering and vacuum drying of the residue at 80° C. for 24 h. For obtaining stable suspension of MXenes the residue powder was added to respective solvents in accordance with the required target concentration and ultrasonicated in a bath for 1 h.

The photoconverter (solar cell) operation principle is going as follows. Light with wavelengths in the range from near UV (λ=300 nm), visible region, to near IR (λ=800 nm) is incident on the photoconverter (solar cell), passes through the transparent electrode and the transport layer with minimum parasitic absorption and reflection losses and is then absorbed by the hybrid perovskite photoactive layer having the molecular formula ABX₃. Light photon absorption by the hybrid perovskite photoactive layer generates electron-positron pairs, i.e., excitons, which have a bond energy of about 40-50 meV and almost freely split into free carriers when exposed to an electric field generated in the device bulk due to the Fermi level mismatch at the absorber layer heterojunctions with electron and hole transport layers. Under positive bias and with the respective external electronic load the device starts generating power in accordance with the photocurrent equation for diode solar cells which can be written as follows:

$$J = {J}_{L} - {J}_{01} \{ exp ⌈ \frac{q ( V + JRs}{kT} ⌉ - 1 \} - {J}_{02} \{ exp ⌈ \frac{q ( V + JRs}{2 kT} ⌉ - 1 \} - \frac{V + JRs}{Rshunt} , \qquad ( 1 )$$

where J is the current density at the device contacts, mA/cm², J_{L} is the current density upon light photon absorption, mA/cm², J₀₁ is the reverse saturation current density for the first junction of the device, mA/cm², J₀₂ is the reverse saturation current density for the second junction of the device, mA/cm², V is the applied external bias, V, R_{S} is the contact resistance, Ohm*cm², and Rₛₕᵤₙₜ is the shunting resistance, Ohm*cm².

The maximum photoconverter (solar cell) power is determined by the VAC filling factor calculated as follows:

$$FF = \frac{{P}_{max}}{{J}_{sc} * {V}_{oc}} = \frac{{J}_{max} * {V}_{max}}{{J}_{sc} * {V}_{oc}} , \qquad ( 2 )$$

where Jₘₐₓ is the device current density at which the product with the bias voltage yields the maximum power, mA/cm², Vₘₐₓ is the device bias voltage at which the product with the photocurrent Jmax yields the maximum power, mA/cm², J_{SC} is the short circuit current density, i.e., the maximum device current density in the absence of bias voltage, mA/cm², and V_{OC} is the open circuit voltage, i.e., maximum device voltage in the absence of photocurrent, V.

The device efficiency is thus calculated using the following equation:

$${C}_{ef} = \frac{{P}_{max}}{{P}_{inc}} = \frac{{J}_{sc} * {V}_{oc} * FF}{{P}_{inc}} , \qquad ( 3 )$$

where P_{inc} is the incident light power density per unit surface, mW/cm².

The novel MXene base materials provided herein are used at heterojunction boundaries and electrode contacts. MXenes are novel and unique 2D materials which were successfully synthesized by selective chemical etching. MXenes have excellent properties e.g. high electrical conductivity (2000-6000 S/cm), chemical stability against most oxidizers, hydrophilic surface, high surface energy which provided for the numerous applications of MXenes (Li-ion batteries, capacitances, gas and bio hazard sensors, electromagnetic screening etc.). However, MXenes may have a variable work function ranging from 1.6 to 6.5 eV in accordance with theoretical calculations. Their work function can be controlled by choosing a suitable transition metal and the chemistry of the surface. During MXene synthesis their surface is terminated predominantly by O, OH and F functional groups which change the electrostatic potential in the vicinity of the surface and affect the electronic structure, e.g. shift the Fermi level.

The capability of MXene work function adjustment over a wide range allows controlling the junction barrier heights by varying the chemistry and functional groups of the MXenes, thus giving rise to new 2D structures which can be considered for use in perovskite solar cells.

Below we will present three exemplified embodiments of perovskite solar cells according to this invention for junction stabilization and charge collection improvement, with the use of MXenes as described hereinabove (Configurations 1-4):
APbX₃ perovskite absorber layer/electron (hole) transport layer;
electron (hole) transport layer/cathode (anode) electrode;
MXene incorporation into electrode bulk for doping and efficient work function reduction aiming at achieving ohmic contacts and increasing the conductivity.

The first embodiment of the invention disclosed herein describes a device structure for junction stabilization and charge collection improvement at the APbX₃ perovskite absorber layer/electron transport layer junction. The perovskite solar cell is fabricated in the p-i-n configuration using one of the liquid deposition methods—spin coating (substrate rotation) onto a glass substrate (2.2 mm) with a transparent FTO conducting electrode (ρₛₕₑₑₜ<15 Ohm/sq). The hole transport layer is made from 10 nm thick wide-band NiO. The photoactive layer (500 nm) is metal-organic perovskite with the molecular formula CH₃NH₃PbI₃, the electron transport layer being PC₆₁BM fullerene derivative (50 nm). The non-transparent silver electrode is deposited by thermal resistive vacuum sputtering. CH₃NH₃⁺ cation diffusion to the cathode and an electrochemical reaction at the photoactive layer/electron transport layer boundary are avoided by depositing a Ti₃C₂Tₓ MXene layer (Configuration 1, MXene work function −3.8 to −4.2 eV, thickness 5-50 nm) from organosol onto the CH₃NH₃PbI₃ perovskite layer surface before electron transport layer deposition for functioning as the diffusion barrier layer.

The second embodiment of the invention disclosed herein describes a device structure for junction stabilization and charge collection improvement at the electron transport layer/cathode junction. The perovskite solar cell is fabricated in the p-i-n configuration using one of the liquid deposition methods—spin coating (substrate rotation) onto a glass substrate (2.2 mm) with a transparent FTO conducting electrode (ρₛₕₑₑₜ<15 Ohm/sq). The hole transport layer is made from 10 nm thick wide-band NiO. The photoactive layer (500 nm) is metal-organic perovskite with the molecular formula CH₃NH₃PbI₃, the electron transport layer being PC₆₁BM fullerene derivative (50 nm). The non-transparent silver electrode is deposited by thermal resistive vacuum sputtering. Silver diffusion into the device bulk and silver oxidation by iodine migrating from the photoactive layer to the electron transport layer surface from organosol are avoided by depositing a Ti₃C₂Tₓ MXene layer (Configuration 3, MXene work function −3.8 to −4.2 eV, thickness 5-50 nm) before cathode deposition for functioning as the diffusion barrier layer and efficiently achieving an ohmic contact.

The third embodiment of the invention disclosed herein describes a device structure for junction stabilization and charge collection improvement at the hole transport layer/anode junction. The perovskite solar cell is fabricated in the p-i-n configuration using one of the liquid deposition methods—spin coating (substrate rotation) onto a glass substrate (1.1 mm) with a transparent ITO conducting electrode (ρ_{surf}<15 Ohm/sq). The hole transport layer is made from 60 nm thick wide-band organic semiconductor PEDOT:PSS. The photoactive layer (500 nm) is metal-organic perovskite with the molecular formula CH₃NH₃PbI₃, the electron transport layer being PC₆₁BM fullerene derivative (50 nm). The non-transparent silver electrode is deposited by thermal resistive vacuum sputtering. Indium diffusion from the ITO electrode into the device bulk and chemical etching of the electrode by the PSS component of the organic semiconductor are avoided by covering the ITO anode layer surface with a Ti₃C₂Tₓ MXene layer (Configuration 4, MXene work function −4.7 to −5.5 eV) for functioning as the diffusion barrier layer and a chemically neutral buffer layer.

The main process steps of thin-film hybrid photoconverter (solar cell) technology are presented below.

a) Ti₃C₂Tₓ MXene was synthesized by selective chemical etching of aluminum from the fine-dispersed Ti₃AlC₂ MAX phase precursor. The etchants were lithium fluoride (LiF) and a 6M hydrochloric acid solution with a Ti₃AlC₂:LiF:HCl molar ratio of 1:7.5:25. Chemical etching was carried out with permanent solution stirring in a magnetic stirrer at a 200 rpm rate at 35° C. for 24 h. Etching was followed by multiple cleaning from reaction products until reaching close-to-neutral pH, filtering and vacuum drying of the residue at 80° C. for 24 h. For obtaining stable suspension of MXenes the residue powder was added to respective solvents following the preset concentration and ultrasonicated in a bath for 1 h.

b) MXene organosol for deposition onto heterojunction boundaries and electrode contacts (in Examples 1-3) was produced by dispersing in dehydrated 0.01-1 wt. % isopropanol. The 5-50 nm layers were deposited by spin-coating at 500 rpm for 5 sec followed by 2500 rpm for 25 sec and drying at 50° C. for 5 min.

c) The NiO hole transport layer was formed by nickel acetate ethylenediamine precursor (1M in ethylene glycol) deposition by spin-coating at 3000 rpm for 60 sec. The layer is then annealed at 300° C. for 60 min.

d) The CH₃NH₃PbI₃ perovskite absorber layer for p-i-n configurations (Examples 1-3) was formed by solution engineering. 1.5 M iodine methylamine and lead iodide solution in dimethylforamide is deposited onto the substrate with the NiO hole transport layer on the surface at 5000 rpm for 6 sec, wherein at the 5^{th} process second 200 microliters dehydrated toluene is cast onto the substrate with the wet layer for inducing the CH₃NH₃PbI₃ crystallization. The crystallization is completed by annealing at 100° C. for 10 min.

e) The electron hole layer for the device p-i-n configuration was formed by spin-coating. Initially PC₆₁BM fullerene derivative is dissolved in 20 mg/ml dehydrated chlorobenzene. The solution is deposited onto the perovskite layer or the preliminarily deposited MXene layer by spin-coating at 1500 rpm for 30 sec. The layer is annealed at 50° C. for 5 min.

f) The non-transparent silver electrode (in Examples 1-3) was deposited by thermal resistive vacuum sputtering at 2*40⁻⁶ Tor through a contact mask. The sputtered metal layer thickness is at least 100 nm.

g) The TiO₂ electron transport layer (in Example 4) was formed using the following route.

A compact TiO₂ layer was deposited onto the FTO substrate by spin-coating (sol-gel) of titanium isopropoxide dispersion in absolute ethanol at 3000 rpm for 30 s. The colloidal dispersion was obtained by drop-by-drop addition of 2.5 ml 2 M HCl solution in ethanol to 350 microliters titanium isopropoxide solution in 2.5 ml ethanol with stirring. The dispersion was ready for use upon becoming clear. Substrate drying at 100° C. for 10 min was followed by sintering at 500° C. for 20 min. At the next step the 400 nm mesoporous TiO₂ layer made from titanium acetylacetonate was printed on a compact layer and dried at 100° C. for 10 min followed by sintering at 500° C. for 20 min. Then the isolating 1.7 micrometer mesoporous ZrO₂ layer was deposited onto the top of the mesoporous TiO₂ layer by template printing followed by drying at 125° C. and sintering at 450° C. for 20 min.

h) The carbon electrode for the photoconverter (solar cell) s of Examples 4 & 5 was formed using the following route.

The 25 um mesoporous carbon layer was scalpel-printed from the top with graphite paste (20 um particle size) and sintered at 400° C. for 30 min. The graphite paste was prepared by mixing 50 wt. % graphite powder in terpinenol (50%), ethyl cellulose (40%) and absolute ethanol (10%) in an agate mortar.

What is claimed is a:

1. Thin-film hybrid Photoconverter consist of transparent substrate, with sequentially deposited transparent electrode and a photoactive layer, which is located between the selectively conducting p- and n-type transport layers, with a nontransparent electrode placed on the top, wherein photoactive layer is made from APbX₃ hybrid perovskites, where
A are organic or inorganic cations e.g. (CH3NH3+; CH5N2+; Cs+; CH6N3+; (NH3)BuCO2H+),
X3 are halide elements of the I; Br; Cl,
and at all the heterojunction boundaries and metal/semiconductor contacts 5-50 nm thick Ti₃C₂Tx MXene layers are placed,
where Tx are functional groups terminating the surface of the 2D materials, Tx=O—, OH—, F—.

2. Photoconverter of claim 1 wherein substrate is made from glass or quartz or plastic.

3. Photoconverter of claim 1 wherein the substrate thickness is 50-750 micrometers.

4. Photoconverter of claim 1 wherein nontransparent electrode is made from Ag or Cu or Al or a ceramic material or carbon nanotubes.

5. Photoconverter of claim 1 wherein MXene is Ti₃C₂Tₓ, where Tₓ is predominantly (55-60%) F— with a work function of 4.2-3.8 eV.

6. Photoconverter of claim 1 wherein MXene is Ti₃C₂Tₓ, where Tₓ is predominantly (65-70%) O— and OH— with a work function of 5.5-4.9 eV.

7. Photoconverter of claim 1 wherein MXene is Ti₃C₂Tₓ, where Tₓ is predominantly (70-75%) O— and F— with a work function of 4.7-3.8 eV.

8. Photoconverter of claim 1 wherein MXene is Ti₃C₂Tₓ, where Tₓ is predominantly (55-60%) O— with a work function of 5.5-4.7 eV.

9. Photoconverter of claim 1 wherein MXene is Ti₃C₂Tₓ, where Tₓ is predominantly (45-50%) OH— with a work function of 4.0-1.8 eV.
